(19) United States
(12) Patent Application Publication
(10) Pub. No.: US 2026/0136899 A1
(43) Pub. Date: May 14, 2026

(54) SEMICONDUCTOR STRUCTURE AND PRODUCTION METHOD THEREOF

(71) Applicant: AAC Technologies Pte. Ltd., Singapore (SG)

(72) Inventors: Chungmin Li, Taiwan (CN); KianHeng Goh, Batu Pahat (MY); Qiang Dan, Shenzhen (CN); Kahkeen Lai, Singapore (SG)

(21) Appl. No.: 18/946,883

(22) Filed: Nov. 13, 2024

(51) Int. Cl. H01L 21/3105; H01L 21/02; H01L 21/027

(52) U.S. Cl. CPC H10P 95/08; H10P 14/6326; H10P 76/204; H10P 95/064

(57) ABSTRACT

Embodiments of the present disclosure relate to the field of semiconductor technology, and provide a semiconductor structure and a production method thereof. The method for producing semiconductor structures includes: providing a substrate; forming an initial photoresist layer on the substrate, and patterning the initial photoresist layer to form a photoresist layer, where a plurality of positioning openings passing through the photoresist layer are defined on the photoresist layer; forming an initial target layer on a surface of the photoresist layer away from the substrate, where the initial target layer fills in the plurality of positioning openings; removing portions of the initial target layer protruding from the surface of the photoresist layer away from the substrate, where portions of the initial target layer filling in the plurality of positioning openings form a target layer; and removing the photoresist layer.

### TECHNICAL FIELD

Embodiments of the present disclosure relate to the field of semiconductor technology, and in particular to a semiconductor structure and a production method thereof.

### BACKGROUND

With the rapid development of semiconductor technologies, the requirements for the material properties of semiconductor devices are also rapidly increasing, in order to obtain semiconductor devices having better performance. Some potential materials have outstanding physical and chemical properties, making them more applicable to the semiconductor devices. Taking organic materials as an example, the organic materials have excellent elasticity, and therefore have much larger vibration amplitudes than those of inorganic materials such as polycrystalline silicon. In view of this, the organic materials are more applicable to vibrating membranes. Moreover, organic materials have excellent moisture resistance and may function as protective layers.

However, the potential materials and photoresist are incompatible due to their similar properties, thereby making it difficult to use the potential materials in a semiconductor production process.

### SUMMARY

Embodiments of the present disclosure provide a semiconductor structure and a production method thereof, which are at least conducive to addressing the problem that a patterned target layer cannot be formed due to the target layer being incompatible with a photoresist layer.

Some embodiments of the present disclosure provide a method for producing semiconductor structures, including: providing a substrate; forming an initial photoresist layer on the substrate, and patterning the initial photoresist layer to form a photoresist layer, where a plurality of positioning openings passing through the photoresist layer are defined on the photoresist layer; forming an initial target layer on a surface of the photoresist layer away from the substrate, where the initial target layer fills in the plurality of positioning openings; removing portions of the initial target layer protruding from the surface of the photoresist layer away from the substrate, where portions of the initial target layer filling in the plurality of positioning openings form a target layer; and removing the photoresist layer.

As an improvement, the target layer includes at least one organic material.

As an improvement, after forming the initial target layer on the surface of the photoresist layer away from the substrate, the method further includes: flattening a surface of the initial target layer away from the substrate; removing the portions of the initial target layer protruding from the surface of the photoresist layer away from the substrate, includes: removing, by etching, the portions of the initial target layer protruding from the surface of the photoresist layer away from the substrate, until the surface of the photoresist layer away from the substrate being exposed.

As an improvement, the initial target layer is formed using a coating process, a hot-pressing process, a rolling process, an electroplating process, or a deposition process.

As an improvement, removing the portions of the initial target layer protruding from the surface of the photoresist layer away from the substrate, includes: removing the portions of the initial target layer protruding from the surface of the photoresist layer away from the substrate using a dry etching process.

As an improvement, removing the photoresist layer, includes: removing the photoresist layer using a first etching process; where during the first etching process, the photoresist layer is etched at a first rate, the target layer is etched at a second rate, and the first rate is greater than the second rate.

As an improvement, providing the substrate, includes: providing an initial substrate; and forming a functional layer on the initial substrate; where the initial substrate and the functional layer form the substrate.

Some embodiments of the present disclosure provide a semiconductor structure produced using a method for producing semiconductor structures, the method includes: providing a substrate; forming an initial photoresist layer on the substrate, and patterning the initial photoresist layer to form a photoresist layer, where a plurality of positioning openings passing through the photoresist layer are defined on the photoresist layer; forming an initial target layer on a surface of the photoresist layer away from the substrate, where the initial target layer fills in the plurality of positioning openings; removing portions of the initial target layer protruding from the surface of the photoresist layer away from the substrate, where portions of the initial target layer filling in the plurality of positioning openings form a target layer; and removing the photoresist layer; where the target layer is patterned, and portions of the substrate are exposed from the target layer.

As an improvement, the target layer includes at least one organic material.

As an improvement, after forming the initial target layer on the surface of the photoresist layer away from the substrate, the method further includes: flattening a surface of the initial target layer away from the substrate; removing the portions of the initial target layer protruding from the surface of the photoresist layer away from the substrate, includes: removing, by etching, the portions of the initial target layer protruding from the surface of the photoresist layer away from the substrate, until the surface of the photoresist layer away from the substrate being exposed.

As an improvement, the initial target layer is formed using a coating process, a hot-pressing process, a rolling process, an electroplating process, or a deposition process.

As an improvement, removing the portions of the initial target layer protruding from the surface of the photoresist layer away from the substrate, includes: removing the portions of the initial target layer protruding from the surface of the photoresist layer away from the substrate using a dry etching process.

As an improvement, removing the photoresist layer, includes: removing the photoresist layer using a first etching process; where during the first etching process, the photoresist layer is etched at a first rate, the target layer is etched at a second rate, and the first rate is greater than the second rate.

As an improvement, providing the substrate, includes: providing an initial substrate; and forming a functional layer on the initial substrate; where the initial substrate and the functional layer form the substrate.

The beneficial effects of the present disclosure lie in: the initial photoresist layer formed on the substrate is etched first, in order to form the photoresist layer having the plurality of positioning openings, and then the target layer is formed in the plurality of positioning openings of the photoresist layer. In this way, the initial photoresist layer is prevented from being formed on the target layer, thereby addressing the technical problem that the initial photoresist layer cannot be patterned due to the material of the target layer being incompatible with the material of the initial photoresist layer, and further addressing the problem that the patterned target layer cannot be formed due to the target layer being incompatible with the photoresist layer.

### BRIEF DESCRIPTION OF DRAWINGS

One or more embodiments are exemplarily illustrated in reference to corresponding accompanying drawing(s), and these exemplary illustrations do not constitute limitations on the embodiments. Unless otherwise stated, the accompanying drawings do not constitute scale limitations. In order to illustrate the technical solutions in related technologies or in the embodiments of the present disclosure more clearly, the drawings to be used in the embodiments will be briefly described below. It is obvious that the drawings mentioned in the following illustration are only some embodiments of the present disclosure. For those of ordinary skill in the art, other drawings may be obtained in accordance with these drawings without any inventive effort.

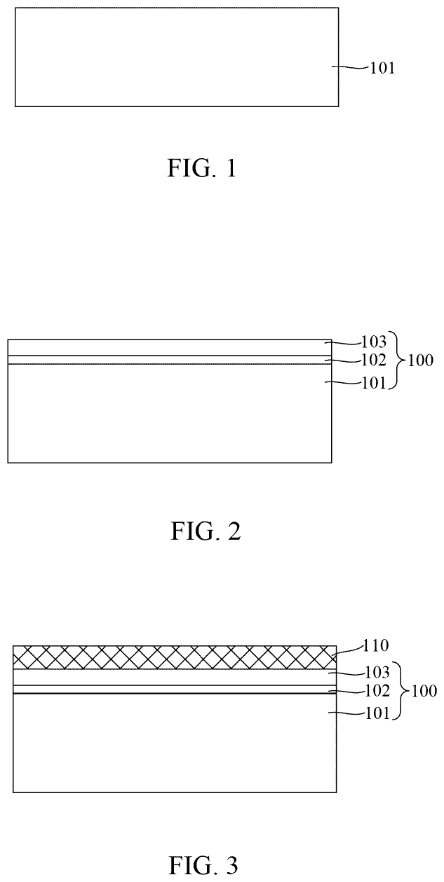

Each of FIGS. 1 to 7 is a schematic diagram showing a respective operation of the method for producing semiconductor structures provided by the embodiments of the present disclosure.

### DETAILED DESCRIPTION OF EMBODIMENTS

It is known from background that it is difficult to use the potential materials in a semiconductor production process.

Specifically, when a potential material is similar to the material of photoresist, directly forming photoresist on the potential material may cause the photoresist to blend with the potential material, resulting in the patterns of photoresist formed by patterning the photoresist not meeting the expected requirements, such that it is difficult to ensure subsequent accurate patterning of the potential material. Therefore, it is difficult to achieve patterning of the potential material by directly forming photoresist on the potential material.

In order to address the above problem, the present disclosure provides a method for producing semiconductor structures. The initial photoresist layer formed on the substrate is etched first, in order to form the photoresist layer having the plurality of positioning openings, and then the target layer is formed in the plurality of positioning openings of the photoresist layer. In this way, the initial photoresist layer is prevented from being formed on the target layer, thereby addressing the technical problem that the initial photoresist layer cannot be accurately patterned due to the material of the target layer being incompatible with the material of the initial photoresist layer, and further addressing the problem that the patterned target layer cannot be formed due to the target layer being incompatible with the photoresist layer.

To make the objects, technical solutions, and advantages of the present disclosure clearer, embodiments of the present disclosure are illustrated in detail with reference to accompanying drawings in the following. A person of ordinary skill in the art can understand that, in the embodiments of the present disclosure, many technical details are provided to make readers better understand the present disclosure. However, even without these technical details and any change and modification based on the following embodiments, technical solutions required to be protected in the present disclosure can be implemented.

Each of FIGS. 1 to 7 is a schematic diagram showing a respective operation of the method for producing semiconductor structures provided by the embodiments of the present disclosure.

Referring to FIGS. 1 to 7, some embodiments of the present disclosure provide a method for producing semiconductor structures, including: providing a substrate 100; forming an initial photoresist layer 110 on the substrate 100, and patterning the initial photoresist layer 110 to form a photoresist layer 111, where a plurality of positioning openings 112 passing through the photoresist layer 111 are defined on the photoresist layer 111; forming an initial target layer 130 on a surface of the photoresist layer 111 away from the substrate 100, where the initial target layer 130 fills in the plurality of positioning openings 112; removing portions of the initial target layer 130 protruding from the surface of the photoresist layer 111 away from the substrate, where portions of the initial target layer 130 filling in the plurality of positioning openings 112 form a target layer 131; and removing the photoresist layer 111.

Thus, the initial photoresist layer formed on the substrate is etched first, in order to form the photoresist layer having the plurality of positioning openings, thereby achieving the accurate patterning of the initial photoresist layer, and ensuring that the shape of the formed photoresist layer meets the expected requirements. Then the target layer is formed in the plurality of positioning openings of the photoresist layer, thereby preventing the initial photoresist layer from being formed on the previously formed initial target layer. In this way, the technical problem that the initial photoresist layer cannot be accurately patterned due to the material of the target layer being incompatible with the material of the initial photoresist layer can be addressed, and therefore the problem that the patterned target layer cannot be formed due to the target layer being incompatible with the photoresist layer can also be addressed.

The method for producing semiconductor structures provided by some embodiments of the present disclosure will be illustrated in detail below in conjunction with the accompanying drawings.

In some embodiments, providing the substrate 100, includes: providing an initial substrate 101, and forming a functional layer on the initial substrate 101. The initial substrate 101 and the functional layer form the substrate 100. That is to say, the substrate 100 may be a single-layer substrate or a substrate having the functional layer.

Referring to FIGS. 1 and 2, in some embodiments, providing the substrate 100, includes: providing the initial substrate 101, and forming the functional layer on the initial substrate 101. The functional layer includes, along a direction away from the initial substrate 101, a first functional layer 102 formed on the initial substrate and a second functional layer 103 formed on the first functional layer.

It is noted that in some other embodiments, the functional layer may include, along the direction away from the initial substrate 101, a first functional layer, a second functional layer, and a third functional layer stacked one on another. The embodiments of the present disclosure do not limit the number of functional layers formed on the initial substrate 101. In practice, the number of functional layers may be determined according to the semiconductor device.

In some embodiments, the initial substrate 101 is a silicon substrate. In some other embodiments, the material of the initial substrate 101 may also be a material that can be directly used in the processes for producing semiconductor devices. For example, the material of the initial substrate 101 may be at least one of silicon-on-insulator (SOI), germanium, silicon carbide, gallium arsenide, sapphire, or the like.

In some embodiments, the functional layer may be made of any type of piezoelectric material. In some examples, the material of the functional layer may include at least one of lead zirconate titanate piezoelectric ceramics, aluminum nitride, aluminum scandium nitrogen, potassium sodium niobate, barium titanate, or zinc oxide.

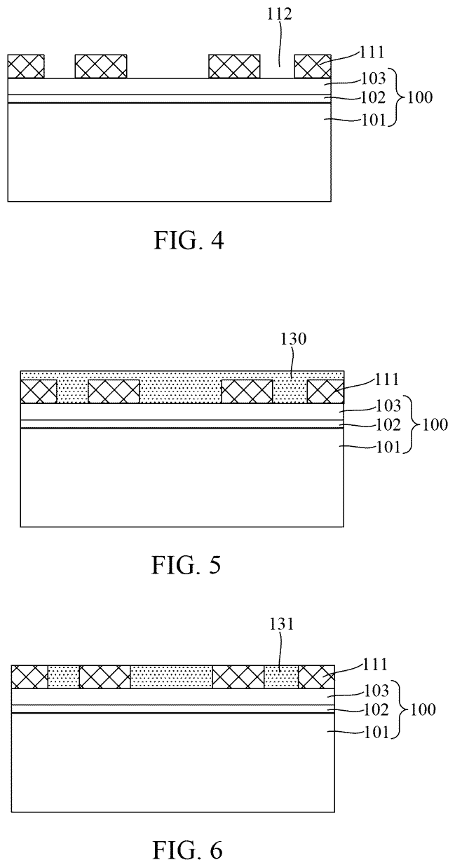

Referring to FIGS. 3 and 4, the initial photoresist layer 110 is formed on the substrate 100. In some examples, forming the initial photoresist layer 110 may include: forming the initial photoresist layer by spin-coating, and performing exposure processing on the initial photoresist layer using a reticle, in order to dissolve and remove the portions of the initial photoresist layer in target areas using developing solution. The remaining portions of the initial photoresist layer outside the target areas form the photoresist layer 111. In this way, the photoresist layer 111 having the plurality of positioning openings 112 can be formed. It is noted that the plurality of positioning openings 112 are in correspondence to the subsequently formed target layer 131.

Referring to FIG. 5, the initial target layer 130 is formed. The initial target layer 130 is formed on the surface of the photoresist layer 111 away from the substrate 100, and the initial target layer 130 fills in the plurality of positioning openings 112. It is noted that the initial target layer 130 has an enough thickness to completely bury the photoresist layer 110.

In some embodiments, the initial target layer 130 may be a dry film layer, a liquid film layer, a paste film layer, or a film layer of any other type.

In some embodiments, the initial target layer 130 is formed using a coating process, a hot-pressing process, a rolling process, an electroplating process, or a deposition process.

In some embodiments, the initial target layer 130 includes at least one organic material.

It is noted that because the photoresist layer 111 has the plurality of positioning openings 112, in some cases, a distance between a top surface of the initial target layer 130 and the substrate 100 is not constant after forming the initial target layer 130. That is to say, the top surface of the initial target layer 130 away from the substrate 100 is not flat. In order to prevent the negative influence on the morphology of the subsequently formed target layer 131 resulted from the uneven surface of the initial target layer 130, in some embodiments, after forming the initial target layer 130, the method further includes: flattening the surface of the initial target layer 130 away from the substrate 100 to make the surface of the initial target layer 130 away from the substrate 100 even.

In some embodiments, the surface of the initial target layer 130 away from the substrate 100 may be flattened using a process of chemical mechanical polishing.

In some embodiments, referring to FIGS. 5 and 6, removing the portions of the initial target layer 130 protruding from the surface of the photoresist layer 111 away from the substrate, includes: removing, by etching, the portions of the initial target layer 130 protruding from the surface of the photoresist layer away from the substrate, until the surface of the photoresist layer 111 away from the substrate being exposed. That is to say, the initial target layer 130 is etched in such a way that the photoresist layer 111 functions as an etching-stop layer, so as to remove the portions of the initial target layer 130 on the top surface of the photoresist layer 111 away from the substrate 100, and retain the portions of the initial target layer 130 filled in the plurality of positioning openings 112 to form the target layer 131. In this way, a patterned target layer 131 can be formed, and during the process of forming the patterned target layer 131, the photoresist layer 111 having the plurality of positioning openings 112 is formed first, and then the plurality of positioning openings 112 are used to form the target layer 131 on specific areas of the substrate 100, thereby addressing the problem that the initial target layer 130 cannot be patterned due to the property of the initial target layer 130 being similar to the property of the photoresist layer 111, and therefore making the selection of the materials of semiconductor devices more flexible and broader.

In some embodiments, removing the portions of the initial target layer 130 protruding from the surface of the photoresist layer 111 away from the substrate, includes: removing the portions of the initial target layer 130 protruding from the surface of the photoresist layer 111 away from the substrate using a dry etching process. In some other embodiments, the portions of the initial target layer 130 protruding from the surface of the photoresist layer 111 away from the substrate may be removed using a wet etching process.

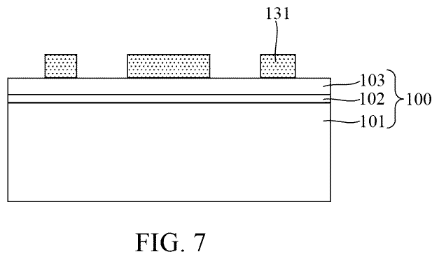

Referring to FIGS. 5 and 6, after removing the portions of the initial target layer 130 protruding from the surface of the photoresist layer 111 away from the substrate, the portions of the initial target layer 130 remained in the plurality of positioning openings 112 form the target layer 131. Referring to FIG. 7, the photoresist layer 111 is removed.

In some embodiments, the target layer 131 includes at least one organic material. The organic materials have excellent elasticity, and therefore have much larger vibration amplitudes than those of inorganic materials such as polycrystalline silicon. In view of this, the organic materials are more applicable to vibrating membranes. Moreover, organic materials have excellent moisture resistance and may function as protective layers. With the method for producing semiconductor structures provided in the embodiments of the present disclosure, patterned organic material layers can be formed, forming semiconductor devices of organic materials is conducive to improvement of the performance of semiconductor devices.

In some embodiments, removing the photoresist layer 111, includes: removing the photoresist layer 111 using a first etching process. During the first etching process, the photoresist layer 111 is etched at a first rate, the target layer 131 is etched at a second rate, and the first rate is greater than the second rate. By removing the photoresist layer 111 using the first etching process in which the photoresist layer 111 is etched at a higher rate, the target layer 131 can be prevented from damage.

In some embodiments, the first etching process includes a wet etching process.

In some embodiments, the material of the target layer is polydimethylsiloxane (PDMS), and the etching solution used in the first etching process includes acetone, because most photoresist layers are soluble in acetone, but PDMS is insoluble in acetone.

In the method for producing semiconductor structures provided in the embodiments of the present disclosure, the photoresist layer 111 having the plurality of positioning openings 112 is formed first, and then the plurality of positioning openings 112 are used to form the target layer 131, thereby addressing the problem that the patterned target layer 131 cannot be formed due to the material of the target layer 131 being incompatible with the material of the photoresist layer 111. In other words, the patterns are not defined using a conventional photolithography process, thereby making the selection of the materials of semiconductor devices more flexible and broader. Moreover, after forming the target layer 131 filling in the plurality of positioning openings 112, the photoresist layer 111 is selectively removed using the solvent in which the photoresist layer 111 is etched at a higher rate, which is conducive to preventing the damage to the target layer 131 caused by the process for removing the photoresist layer 111.

Some embodiments of the present disclosure provide a semiconductor structure produced using the method for producing semiconductor structures as illustrated in the embodiments hereinbefore. It is noted that the same or similar parts as the embodiments illustrated above will not be repeated here.

Referring to FIG. 9, the semiconductor structure includes: a substrate 100 and a patterned target layer 131. The target layer 131 is formed on the substrate 100, and portions of the substrate 100 are exposed from the target layer 131.

In some embodiments, the substrate 100 includes an initial substrate 101 and a functional layer formed on the initial substrate 101.

In some embodiments, the functional layer includes, along a direction away from the initial substrate 101, a first functional layer 102 formed on the initial substrate and a second functional layer 103 formed on the first functional layer.

It is noted that in some other embodiments, the functional layer may include, along the direction away from the initial substrate 101, a first functional layer, a second functional layer, and a third functional layer stacked one on another. The embodiments of the present disclosure do not limit the number of functional layers formed on the initial substrate 101. In practice, the number of functional layers may be determined according to the semiconductor device.

In some embodiments, the initial substrate 101 is a silicon substrate. In some other embodiments, the material of the initial substrate 101 may also be a material that can be directly used in the processes for producing semiconductor devices. For example, the material of the initial substrate 101 may be at least one of SOI, germanium, silicon carbide, gallium arsenide, sapphire, or the like.

In some embodiments, the material of the target layer 131 may be poly-p-xylylene or other polymers.

The semiconductor structure provided in the present disclosure is produced using the method for producing semiconductor structures as illustrated in the embodiments hereinbefore. In the semiconductor structure provided in the present disclosure, the target layer may be made of a material having excellent properties similar to the properties of the photoresist layer. In this way, materials having excellent properties can be used to produce the semiconductor structure, thereby forming corresponding semiconductor devices using the semiconductor structures, which is conducive to improvement of performance of the semiconductor devices.

Those skilled in the art shall understand that the embodiments illustrated above are specific embodiments for implementing the present disclosure. In practice, various changes may be made to these embodiments in form and in detail without departing from the spirit and scope of the disclosure. Those skilled in the art can make any modifications and changes without departing from the spirit and scope of the present disclosure. Therefore, the scope of protection of the present disclosure shall be subject to the scope limited by the appended claims.

1. A method for producing semiconductor structures, comprising:
providing a substrate;
forming an initial photoresist layer on the substrate, and patterning the initial photoresist layer to form a photoresist layer, wherein a plurality of positioning openings passing through the photoresist layer are defined on the photoresist layer;
forming an initial target layer on a surface of the photoresist layer away from the substrate, wherein the initial target layer fills in the plurality of positioning openings;
removing portions of the initial target layer protruding from the surface of the photoresist layer away from the substrate, wherein portions of the initial target layer filling in the plurality of positioning openings form a target layer; and
removing the photoresist layer.

2. The method according to claim 1, wherein the target layer includes at least one organic material.

3. The method according to claim 1, after forming the initial target layer on the surface of the photoresist layer away from the substrate, further including:
flattening a surface of the initial target layer away from the substrate;
wherein removing the portions of the initial target layer protruding from the surface of the photoresist layer away from the substrate, includes:
removing, by etching, the portions of the initial target layer protruding from the surface of the photoresist layer away from the substrate, until the surface of the photoresist layer away from the substrate being exposed.

4. The method according to claim 1, wherein the initial target layer is formed using a coating process, a hot-pressing process, a rolling process, an electroplating process, or a deposition process.

5. The method according to claim 3, wherein the initial target layer is formed using a coating process, a hot-pressing process, a rolling process, an electroplating process, or a deposition process.

6. The method according to claim 1, wherein removing the portions of the initial target layer protruding from the surface of the photoresist layer away from the substrate, includes:
removing the portions of the initial target layer protruding from the surface of the photoresist layer away from the substrate using a dry etching process.

7. The method according to claim 3, wherein removing the portions of the initial target layer protruding from the surface of the photoresist layer away from the substrate, includes:
removing the portions of the initial target layer protruding from the surface of the photoresist layer away from the substrate using a dry etching process.

8. The method according to claim 1, wherein removing the photoresist layer, includes:
removing the photoresist layer using a first etching process;
wherein during the first etching process, the photoresist layer is etched at a first rate, the target layer is etched at a second rate, and the first rate is greater than the second rate.

9. The method according to claim 1, wherein providing the substrate, includes:
providing an initial substrate; and
forming a functional layer on the initial substrate;
wherein the initial substrate and the functional layer form the substrate.

10. A semiconductor structure, produced using a method for producing semiconductor structures, wherein the method comprises:
providing a substrate;
forming an initial photoresist layer on the substrate, and patterning the initial photoresist layer to form a photoresist layer, wherein a plurality of positioning openings passing through the photoresist layer are defined on the photoresist layer;
forming an initial target layer on a surface of the photoresist layer away from the substrate, wherein the initial target layer fills in the plurality of positioning openings;
removing portions of the initial target layer protruding from the surface of the photoresist layer away from the substrate, wherein portions of the initial target layer filling in the plurality of positioning openings form a target layer; and
removing the photoresist layer;
wherein the target layer is patterned, and portions of the substrate are exposed from the target layer.

11. The semiconductor structure according to claim 10, wherein the target layer includes at least one organic material.

12. The semiconductor structure according to claim 10, after forming the initial target layer on the surface of the photoresist layer away from the substrate, the method further includes:
flattening a surface of the initial target layer away from the substrate;
wherein removing the portions of the initial target layer protruding from the surface of the photoresist layer away from the substrate, includes:
removing, by etching, the portions of the initial target layer protruding from the surface of the photoresist layer away from the substrate, until the surface of the photoresist layer away from the substrate being exposed.

13. The semiconductor structure according to claim 10, wherein the initial target layer is formed using a coating process, a hot-pressing process, a rolling process, an electroplating process, or a deposition process.

14. The semiconductor structure according to claim 12, wherein the initial target layer is formed using a coating process, a hot-pressing process, a rolling process, an electroplating process, or a deposition process.

15. The semiconductor structure according to claim 10, wherein removing the portions of the initial target layer protruding from the surface of the photoresist layer away from the substrate, includes:
removing the portions of the initial target layer protruding from the surface of the photoresist layer away from the substrate using a dry etching process.

16. The semiconductor structure according to claim 12, wherein removing the portions of the initial target layer protruding from the surface of the photoresist layer away from the substrate, includes:
removing the portions of the initial target layer protruding from the surface of the photoresist layer away from the substrate using a dry etching process.

17. The semiconductor structure according to claim 10, wherein removing the photoresist layer, includes:
removing the photoresist layer using a first etching process;
wherein during the first etching process, the photoresist layer is etched at a first rate, the target layer is etched at a second rate, and the first rate is greater than the second rate.

18. The semiconductor structure according to claim 10, wherein providing the substrate, includes:
providing an initial substrate; and
forming a functional layer on the initial substrate;
wherein the initial substrate and the functional layer form the substrate.
